(19) United States
(12) Patent Application Publication
(10) Pub. No.: US 2008/0179643 A1
(43) Pub. Date: Jul. 31, 2008

(54) CMOS image sensor and method of manufacturing the same

(76) Inventor: Atsushi Okamoto, Chiba-shi (JP)

Correspondence Address: BRUCE L. ADAM, ESQ;ADAMS & WILKS, SUITE 1231, 17 BATTERY PLACE, NEW YORK, NY, 10004, US

(21) Appl. No.: 12/011,382

(22) Filed: Jan. 24, 2008

(30) Foreign Application Priority Data
Jan. 29, 2007 (JP) 2007-017392

(51) Int. Cl. H01L 31/0216; H01L 31/112

(52) U.S. Cl. 257/292; 438/73; 257/E31.119; 257/E31.079

(57) ABSTRACT

Spin-on-glass (SOG) or resist is coated on a passivation film formed on a photodiode region, and then a surface layer of the passivation film together with the SOG or the resist is etched back, to thereby remove irregularities of the surface of the passivation film and to optically planarize the passivation film. As a result, attenuation of light due to reflection, absorption, scattering, and interference is prevented, and a reduction in sensitivity due to variation in thickness of the passivation film is improved.

### BACKGROUND OF THE INVENTION

1. Field of the Invention

The present invention relates to a CMOS image sensor used in a device for capturing and transmitting image information, such as a facsimile, an image scanner, and an electronic camera and also relates to a method of manufacturing the CMOS image sensor.

2. Description of the Related Art

FIG. 3 shows an exemplary circuit diagram of a conventional CMOS image sensor. In a sensor circuit 10 of the CMOS image sensor, a reset transistor 11 serving as a switching element for resetting a photodiode 12 to an appropriate voltage, and an amplifier circuit 13 for amplifying light induced charges accumulated in the photodiode 12 are connected to the photodiode 12 including a PN junction.

Optical information can be obtained continuously through following three operations: a reset operation in which the reset transistor 11 is turned on so as to reset the photodiode 12 to a reset voltage to a satisfactory extent; an accumulation operation in which the reset transistor 11 is turned off so as to accumulate light induced charges in the photodiode 12 for a predetermined period of time; and a read operation in which the amplifier circuit 13 is turned on so as to amplify the light induced charges accumulated in the photodiode 12 for reading.

Temporal storage of amplified signal may also be performed in the read operation by using a holding circuit 20 including a storage capacitor 21 and two switching transistors (22A and 22B).

The switching transistor 22A is turned on during the read operation, and the signal is stored in the storage capacitor 21 as an electrical charge by the amplifier circuit 13. The switching transistor 22A is then turned off and the switching transistor 22B is later turned on after an arbitrary holding time, thereby permitting the signal read from the storage capacitor 21.

Separate reading of the signal from the holding circuit in an arbitrary order is also possible after a series of operations, that is, the reset operation, the accumulation operation, and the read operation are collectively performed with respect to a plurality of photodiodes.

FIG. 4 is a schematic cross-sectional diagram showing an example of a photodiode portion of a conventional CMOS image sensor. An N-well region 2 and a local oxidation of silicon (LOCOS) oxide film 3 are formed on a p-type silicon substrate 1. In addition, an N⁺ region 4 with an n-type impurity concentration higher than that of the N-well region 2 is formed in the N-well region 2. An intermediate insulating film 5 is formed on the p-type silicon substrate 1, the N-well region 2, and the N⁺ region 4. A metal line 6 is connected to the N⁺ region 4. Further, a passivation film 7 is formed on the intermediate insulating film 5 and the metal line 6. It is known that an optical layer is formed on the passivation film 7 to thereby improve optical transparency thereof (for example, see JP 2001-060679 A).

In particular, in a case of using a low intensity light source, absorption of light by the passivation film formed on the photodiode region cannot be avoided. In addition light attenuation is a problem in which light entering an edge portion thereof is refracted on the way through the film before reaching the photodiode region since vicinity of the edge of the passivation film formed on the photodiode region is not flat. As a result, there arises a problem of lowering in sensitivity in which an amount of electrical signals, such as a voltage, with respect to the light irradiated on the photodiode region reduces.

### SUMMARY OF THE INVENTION

In order to solve the above-mentioned problems, according to the present invention, there is provided a CMOS image sensor formed by the following manufacturing method. In a process of manufacturing the CMOS image sensor, a passivation film is formed, and then spin-on-glass (SOG) or resist is coated thereon. Further, a thin film obtained by coating an entire surface layer of the passivation film is etched back, to thereby remove irregularities of a surface of the passivation film. Thus, the CMOS image sensor in which the passivation film is optically planarized is formed.

As described above, according to the present invention, the passivation film formed on a photodiode region is planarized, thereby preventing attenuation of light due to reflection, absorption, scattering, and interference. In addition, the surface of the passivation film for protecting the photodiode is optically planarized, thereby making it possible to realize a high-sensitive photodiode with little variation in thickness of the passivation film. The present invention provides a high-resolution CMOS image sensor having the photodiode mounted therein, with high quality and at low cost.

### BRIEF DESCRIPTION OF THE DRAWINGS

In the accompanying drawings:

FIGS. 1A, 1B, 1C, and 1D are schematic cross-sectional diagrams, in an order of steps, each showing a manufacturing process for a photodiode portion of a CMOS image sensor according to the present invention;

FIG. 2 is a schematic cross-sectional diagram showing a photodiode portion of a CMOS image sensor according to an embodiment of the present invention;

FIG. 3 is a circuit diagram showing an example of a CMOS image sensor of a related art; and

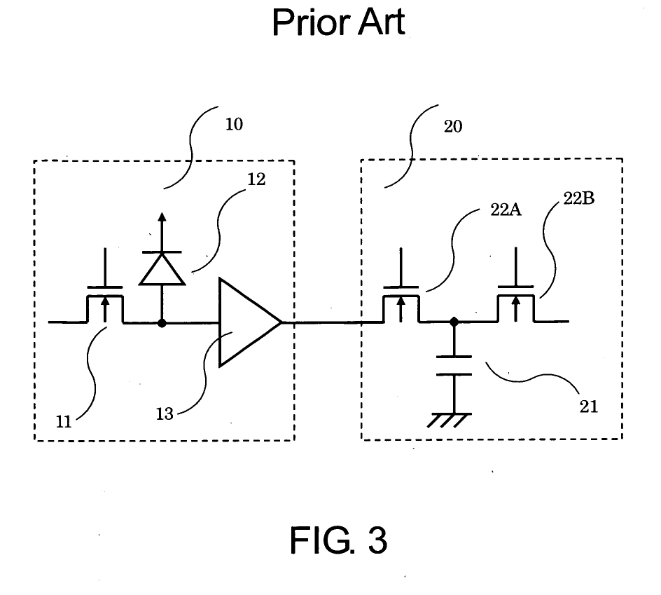

FIG. 4 is a schematic cross-sectional diagram showing an example of a photodiode portion of the CMOS image sensor of the related art.

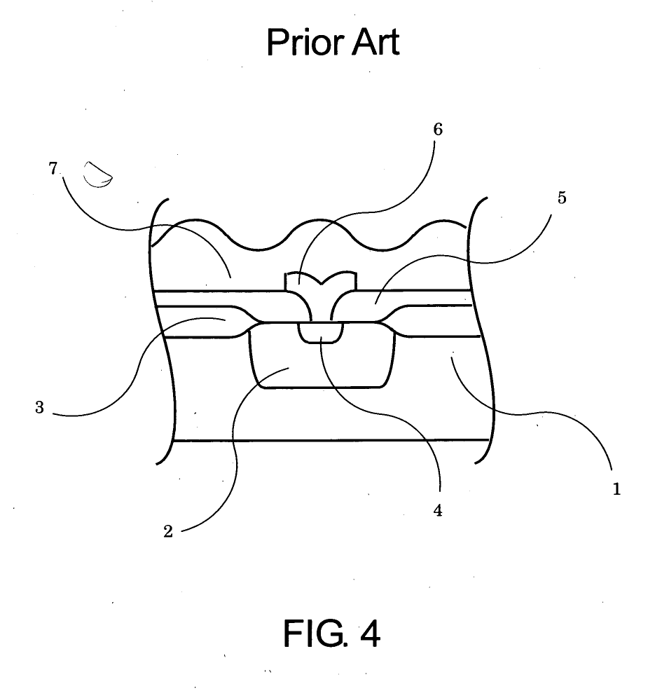

### DETAILED DESCRIPTION OF THE PREFERRED EMBODIMENTS

Exemplary embodiments of the present invention will be described with reference to the accompanying drawings.

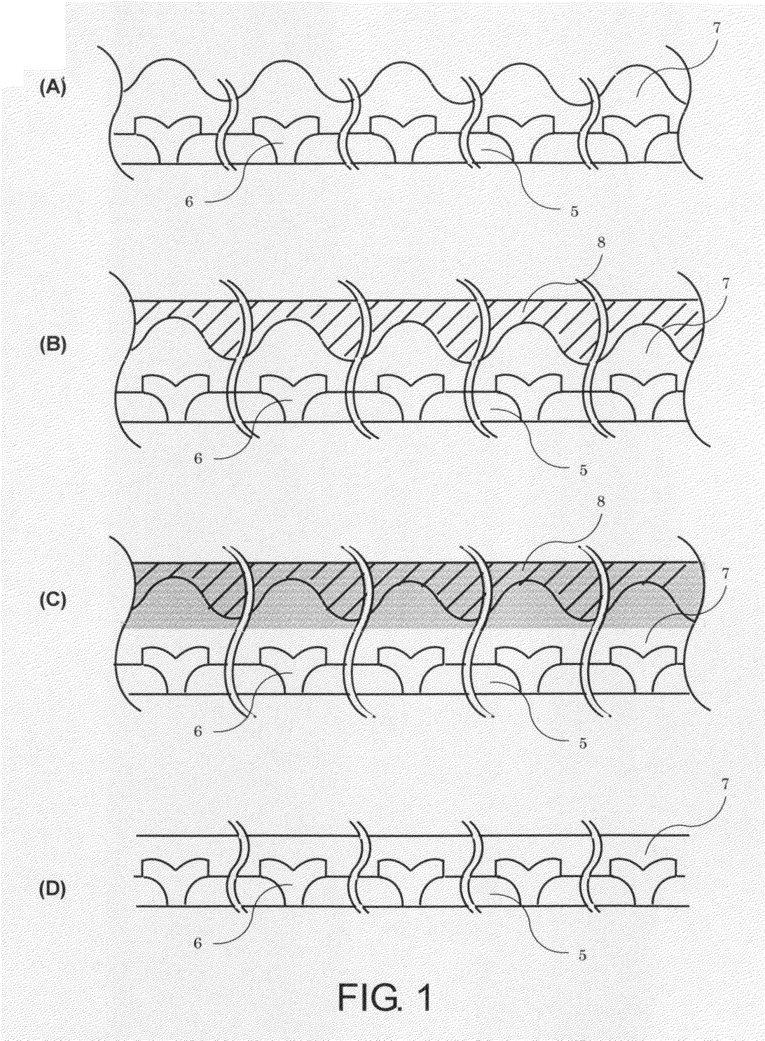

FIGS. 1A, 1B, 1C, and 1D are schematic cross-sectional diagrams, in an order of steps, each showing a manufacturing process for a photodiode portion of a CMOS image sensor according to the present invention. A surface of a passivation film 7, which is formed on an intermediate insulating film 5 and a metal line 6 by a plasma CVD method, is hardly planarized due to great variation in thickness of the passivation film 7 particularly near a wafer edge at which the uniformity of metal density is relatively deteriorated (see FIG. 1A). For this reason, a spin-on-glass (SOG) 8 is coated on the passivation film 7 thus formed, to thereby planarize the surface of the passivation film 7 (see FIG. 1B). It should be noted that, transmittance, a refractive index, and the like of the SOG 8 are different from those of the passivation film 7, whereby a quantity of light reaching a photodiode region becomes uneven. Accordingly, apart of the surface of each of the SOG 8 and the passivation film 7 is removed by etch back (represented as a gray area shown in FIG. 1C). Since the surface of the passivation film 7 thus obtained is planarized, and is optically uniform and flat, attenuation of light due to reflection, absorption, scattering, and interference can be prevented, thereby making it possible to realize a high-sensitive photodiode (see FIG. 1D).

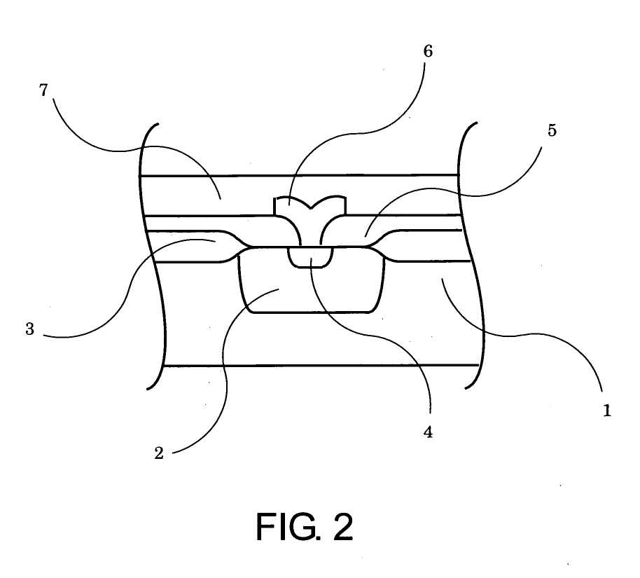

FIG. 2 is a schematic cross-sectional diagram showing a photodiode portion of a CMOS image sensor according to an embodiment of the present invention. An N-well region 2 and a LOCOS oxide film 3 are formed on a p-type silicon substrate 1. In addition, an N⁺ region 4 with an n-type impurity concentration higher than that of the N-well region 2 is formed in the N-well region 2. An intermediate insulating film 5 is formed on the p-type silicon substrate 1, the N-well region 2, and the N⁺ region 4. A metal line 6 is connected to the N⁺ region 4 via a contact hole formed in the intermediate insulating film 5. In a photodiode region of the conventional CMOS image sensor, the passivation film 7 is formed on the intermediate insulating film 5 and the metal line 6 and is not flat. On the contrary the CMOS image sensor according to the present invention has a structure in which the passivation film formed on the photodiode region is planarized.

SOG or resist is coated on the passivation film formed on the photodiode region, and then a surface layer of the passivation film together with the SOG or the resist is etched back, to thereby remove irregularities of the surface of the passivation film and realize a optically flat surface of the passivation film. As a result, the attenuation of light due to reflection, absorption, scattering, and interference can be prevented, and a reduction in sensitivity due to variation in thickness of the passivation film near the edge of the passivation film formed on the photodiode region can be improved.

What is claimed is:

1. A CMOS image sensor, having a photodiode and a MOS transistor formed on a silicon substrate, comprising:
an intermediate insulating film disposed on a region of the photodiode;
a metal line connected to the region of the photodiode through a contact hole disposed in the intermediate insulating film; and
an optically flat and etched back passivation film having a small thickness on the metal line and having a large thickness on a region in absence of the metal line.

2. A method of manufacturing a CMOS image sensor, comprising:
forming an intermediate insulating film on a semiconductor substrate;
forming a metal line;
depositing a passivation film on an entire surface of the semiconductor substrate; and
applying spin-on-glass (SOG) to a surface of the passivation film before etching back to planarize a surface layer of the passivation film.

3. A method of manufacturing a CMOS image sensor, comprising:
forming an intermediate insulating film on a semiconductor substrate;
forming a metal line;
depositing a passivation film on an entire surface of the semiconductor substrate; and
applying resist to a surface of the passivation film before etching back to planarize a surface layer of the passivation film.
